(19) United States
(12) Patent Application Publication
(10) Pub. No.: US 2013/0269997 A1
(43) Pub. Date: Oct. 17, 2013

(54) ELECTROMAGNETIC INTERFERENCE SHIELDING

(71) Applicants: Glenn C. Simon, Auburn, CA (US); David G. Rohrer, Auburn, CA (US); David L. Mallery, Roseville, CA (US)

(72) Inventors: Glenn C. Simon, Auburn, CA (US); David G. Rohrer, Auburn, CA (US); David L. Mallery, Roseville, CA (US)

(21) Appl. No.: 13/444,081

(22) Filed: Apr. 11, 2012

(51) Int. Cl. H05K 9/00; H05K 13/00

(52) U.S. Cl. 174/350; 29/592.1

(57) ABSTRACT

A wire defining a repeating pattern is removably joined to a flange having apertures defined therein. The wire includes contact portions to make electrically-conductive contact with a device supported by a chassis. The device can be cooled by air flow through the apertures of the flange while being protected against electromagnetic interference (EMI). The wire and the flange can be respectively formed from various metals and are separable from each other for recycling or other purposes.

### BACKGROUND

Various kinds of electronic devices are susceptible to performance degradation or disruption by electromagnetic interference (EMI). Conversely, such or other electronic devices produce EMI that must be attenuated or contained to avoid detrimental effect on other or neighboring devices. Furthermore, such devices usually require some amount of convective cooling during normal operation. The present teachings address the foregoing and related concerns.

### BRIEF DESCRIPTION OF THE DRAWINGS

The present embodiments will now be described, by way of example, with reference to the accompanying drawings, in which:

FIG. 1 depicts an isometric-like view of a flange according to one example of the present teachings;

FIG. 2 depicts an isometric-like view of a wire gasket according to another example;

FIG. 3A depicts an isometric-like top view of an EMI shielding apparatus according to another example;

FIG. 3B depicts an isometric-like bottom view of the EMI shielding apparatus of FIG. 3A;

FIG. 4 depicts an isometric-like view of system according to another example of he present teachings;

FIG. 5 depicts an elevation section of a portion of a system according to another example;

FIG. 6 depicts a flow diagram of a method according to the present teachings.

### DETAILED DESCRIPTION

### Introduction

Apparatus and methods related to electromagnetic interference (EMI) shielding are provided. A wire defines a repeating pattern and is removably joined to a flange, the flange having through apertures defined therein. The wire includes contact portions to make electrically-conductive contact with a device supported by a chassis, or with another adjacent entity. The device can be cooled by air flow through the apertures of the flange and by way of spaces or gaps defined by the pattern of the wire. The device is also protected against EMI. The wire and the flange can be respectively formed from various metals and are separable from each other for recycling, respective re-use or disposal, or other purposes.

In one example, an apparatus includes a flange defining a plurality of through apertures. The apparatus also includes a wire gasket defining a repeating pattern of finger portions and contact portions. The wire gasket is configured to be removably joined to the flange by way of the through apertures. The wire gasket is to electrically couple the flange to an adjacent entity by way of the contact portions. The wire gasket defines an electromagnetic interference (EMI) shield.

In another example, a method includes forming a wire gasket to define an alternating pattern of finger portions and raised contact portions. The method also includes forming a sheet metal to define a flange having a plurality of through apertures. The method additionally includes removably joining the wire gasket to the flange by way of the through apertures to define an EMI shielding device.

In yet another example, a method includes forming an EMI shielding device including a wire gasket and a flange. The flange defines apertures there through. The method also includes making compliant electrically conductive contact between the EMI shielding device and an electronic device supported by a chassis. The method further includes cooling the electronic device by way of fluid flow through the apertures.

### Illustrative Flange

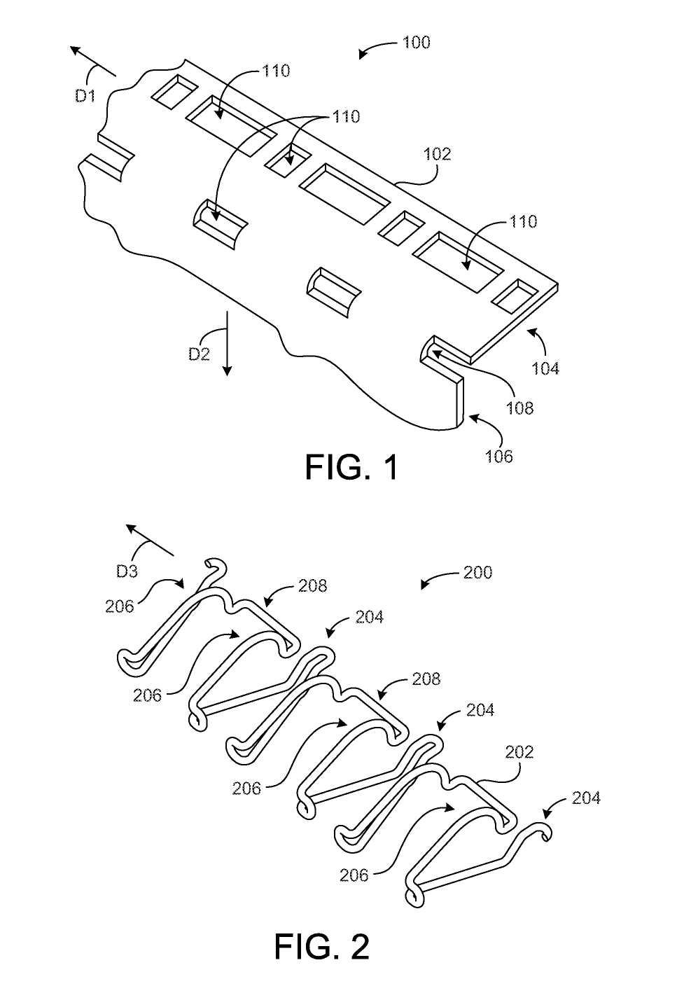

Attention is now turned to FIG. 1, which depicts a flange 100 according to the present teachings. The flange 100 is illustrative and non-limiting with respect to the present teachings. Other flanges having other respective characteristics can also be defined and used.

The flange 100 is formed from a sheet metal 102. Non-limiting examples of the sheet metal 102 include pre-plated steel, aluminum, brass, copper and so on. Other suitable materials can also be used. The flange 100 is formed to define a first portion 104, and a second portion 106 generally orthogonal to the first portion 104. The first portion 104 transitions to the second portion 106 by way of a radiused portion (or bend) 108.

The flange 100 is also formed to define a plurality of through apertures 110. The first portion 104 can continue along a direction “D1” so as to define a lengthwise aspect or dimension of the flange 100. The second portion 106 can continue in the lengthwise direction D1, as well as along a direction “D2” so as to define a height-wise dimension of the flange 100. The second portion 106 can be formed to define (or a portion of) a face of an electronic device, a wall of a chassis, and so on. The second portion 106 can be configured to define other entities or portions thereof, as well.

The through apertures 110 are configured to receive respective portions of a wire element described hereinafter. In one non-liming usage, the through apertures 110 are also configured to allow fluid flow (such as air flow) there through so to cool an electronic device.

### Illustrative Wire Gasket

Reference is made now to FIG. 2, which depicts a wire gasket 200. The wire gasket 200 is illustrative and non-limiting with respect to the present teachings. Other wire gaskets having other respective characteristics can also be defined and used.

The wire gasket 200 is formed from a metal spring wire 202. Non-limiting examples of the metal wire 202 include various spring steels (plated or non-plated), stainless steel, beryllium copper, and so on. Other suitable materials having respective spring-like characteristics can also be used. The wire gasket 200 is formed to define a repeating pattern of finger portions 204 and raised contact portions 206. The wire gasket 200 also defines a plurality of shoulder portions 208.

The repeating pattern can continue along a direction “D3” so as to define a lengthwise aspect or dimension of the wire gasket 200. The wire gasket 200 is configured to be joined to the flange 100 be way of grasping engagement. Specifically, the finger portions 204 are received in (or through) some of the through apertures 110, while the shoulder portions 208 are received in others of the through apertures 110, as further described below.

### Illustrative EMI Shielding Apparatus

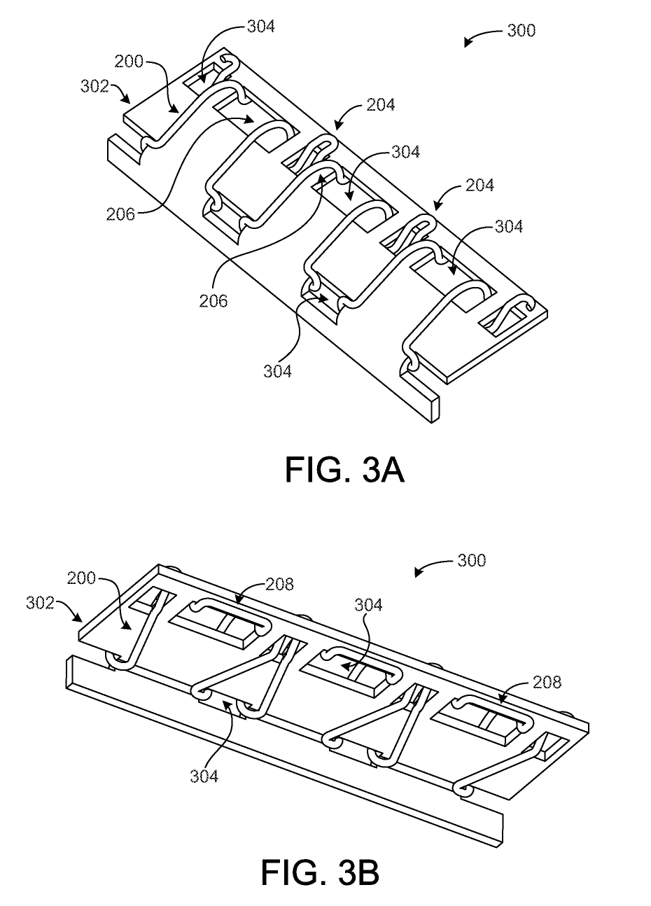

Attention is now turned to FIG. 3A, which depicts a top view of an EMI shielding apparatus (apparatus) 300. The apparatus 300 is illustrative and non-limiting with respect to the present teachings. Other apparatus, assemblages, devices and systems can also be defined or used.

The apparatus 300 includes a flange 302. The flange 302 is analogous the flange 100 described above, and defines respective through apertures 304. The apparatus also includes the wire gasket 200 as described above. The wire gasket 200 is removably joined to the flange 300 by way of grasping or grip-like engagement of the finger portions 204 and the shoulder portions 208 received in respective ones of the through apertures 304.

The raised contact portions 206 of the wire gasket 200 extend generally away from the flange 302 and have a curvilinear or “arc-like” form factor. The raised contact portions 206 are configured to make electrically conductive contact with another entity near adjacency to the flange 302. The flange 302 and such other entity would thus be in electrical communication with each other during typical normal use as described hereinafter.

Reference is now turned to FIG. 3B, which depicts a bottom view of the EMI shielding apparatus 300. The shoulder portions 208 and the finger portions 204 are in loaded contact with the flange 302 by virtue of the spring-like, compliant characteristic of the wire gasket 200.

### Illustrative System

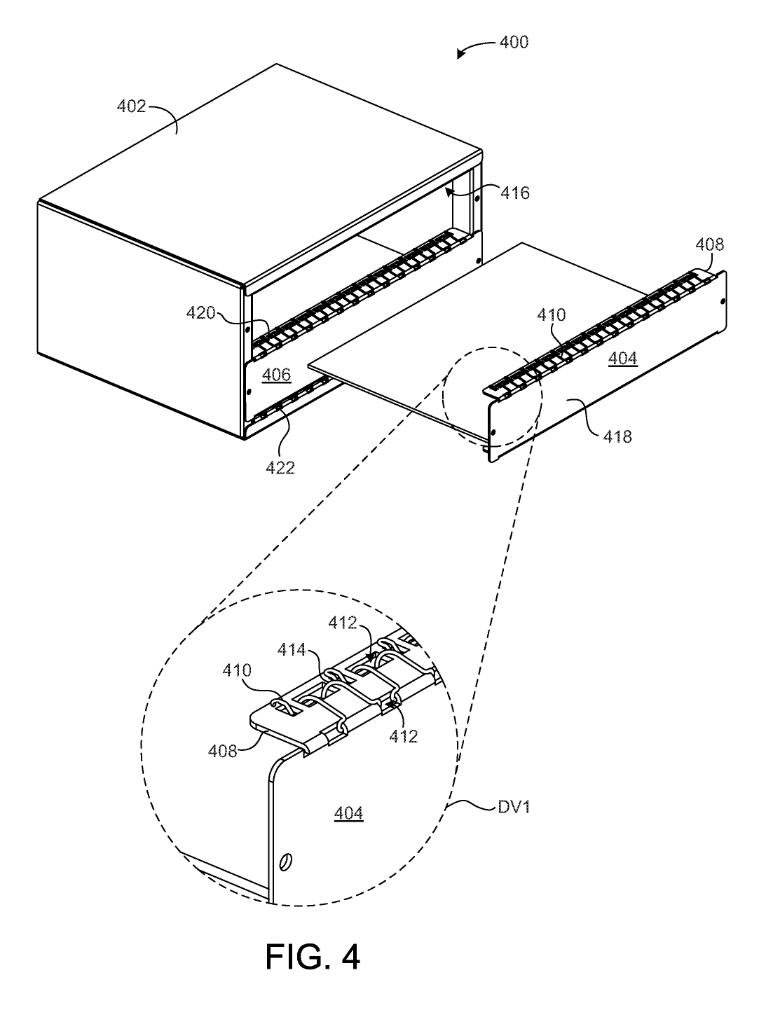

Attention is turned now to FIG. 4, which depicts a system 400 according to one example of the present teachings. The system 400 is illustrative and non-limiting in nature, and other systems, devices and configurations are contemplated by the present teachings.

The system 400 includes a chassis 402. The chassis 402 is formed from or includes walls constructed from one or more sheet metals such as aluminum, brass, copper, steel, or another suitable material. The chassis 402 is configured to slidingly receive and support a plurality of electronic devices 404 and 406 and to shield those devices 404 and 406 from EMI. The electronic device 404 is depicted partially withdrawn from the chassis 402 for purposes of illustration and clarity. The electronic device 406 is depicted fully received within the chassis 402.

Each electronic device 404 and 406 can include any electronic, electrical or electromechanical constituency. Non-limiting examples of such electronic devices 404 and 406 includes network routers, power supplies, signal amplifiers, process control instrumentation, digital and/or wireless communications transceivers, and so on. Each electronic device 404 and 406 is configured to be at least partially received within and supported by the chassis 400 during typical normal operations.

The electronic device 404 includes a flange 408 and a wire gasket 410 in accordance with the present teachings. Specifically, the wire gasket 410 is joined to the flange 408 by way of through apertures 412 and spring-like compliant gripping as depicted in detail view “DV1”.

Raised contact portions 414 of the wire gasket 410 are configured to make compliant, electrically conductive contact with a flange (or wall) portion 416 of the chassis 400 when the electronic device 404 is full received therein. The flange 408 transitions from the portion in supportive engagement with the wire gasket 410 to define a face portion 418 of the electronic device 404

In turn, the electronic device 406 includes a wire gasket 420 supported so as to make electrically conductive contact with the electronic device 404 when both devices are fully received within the chassis 402. Additionally, the chassis 402 includes a wire gasket 422 supported so as to make electrically conductive contact with the electronic device 406 when it is fully received within the chassis 402.

The wire gaskets 410, 420 and 422, respectively, function to protect the electronic devices 404 and 406 against EMI, while the wire gaskets 410, 420 and 422 and the through apertures 412 allow for convective cooling (e.g. air flow or exchange) during typical normal operation of the system 400. In particular, the respective gaps defined between adjacent entities by virtue of the form factor of the wire gaskets 410, 420 and 422 define airflow pathways for cooling the electronic devices 404 and 406.

### Illustrative Portion of System

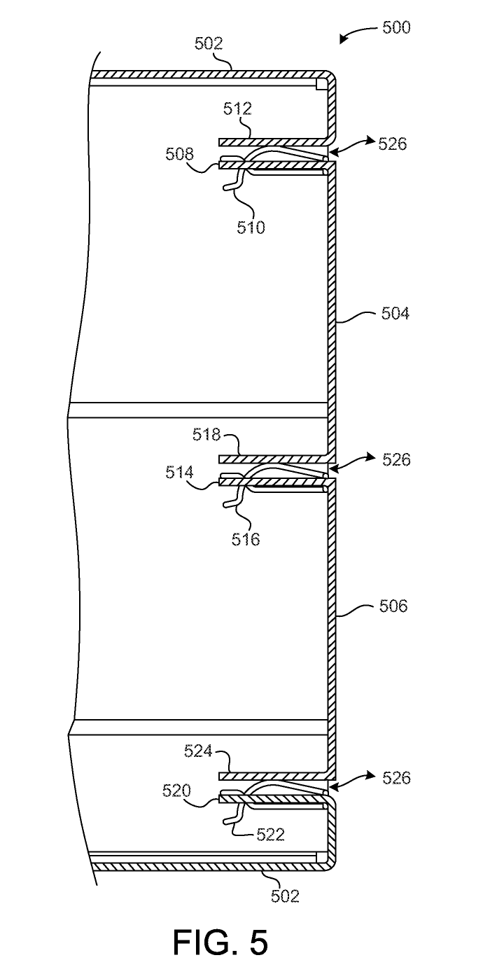

Reference now made to FIG. 5, which depicts a sectional view of a system 500 according to another example of the present teachings. The system 500 is illustrative and non-limiting in nature, and other systems, devices and configurations are contemplated by the present teachings.

The system 500 includes a chassis 502 formed of metal and analogous to the chassis 402 described above. The system also includes respective electronic devices 504 and 506 that are supported in fully-received relationship with the chassis 502.

The electronic device 504 includes a flange 508 supporting (or joined to) a wire gasket 510 in accordance with the present teachings. The wire gasket 510 is in electrically conductive contact with a flange portion 512 of the chassis 502. The electronic device 506 includes a flange 514 supporting (or joined to) a wire gasket 516. The wire gasket 516 is in electrically conductive contact with a lower wall (or flange) portion 518 of the electronic device 504. Additionally, the chassis 502 includes a flange 520 supporting a wire gasket 522. The wire gasket 522 is in electrically conductive contact with a lower wall (or flange) portion 524 of the electronic device 506.

The respective wire gaskets 508, 514 and 520 function to protect electronic circuitry and devices of the electronic devices 504 and 506 against EMI during typically normal operations. The wire gaskets 508, 514 and 520 and through apertures (e.g., 412) they respectively engage also permit convective coolant or air flow through the chassis 502 as depicted by respective double-arrows 526.

### Illustrative Method

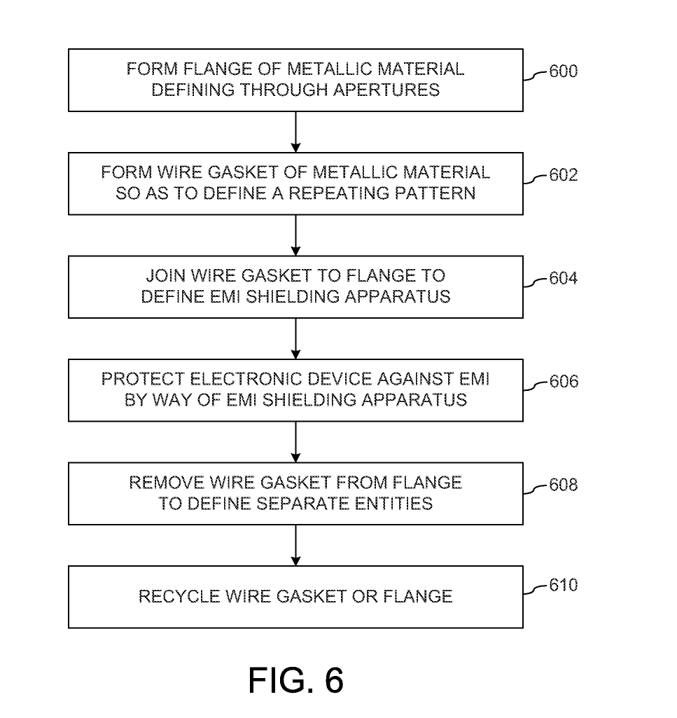

Reference is made now to FIG. 6, which is a flow diagram of a method according to the present teachings. The flow diagram of FIG. 6 depicts particular method steps and order of execution. However, the present teachings contemplate other methods including other steps, omitting one or more of the depicted steps, or proceeding in other orders of execution. Thus, the method of FIG. 6 is non-limiting with respect to the present teachings. Reference is also made to FIG. 4 in the interest of Illustrating the method of FIG. 6.

At 600, a flange is formed of metallic material so as to define though apertures, For purposes of a present illustration, a flange 408 is formed from sheet metal having respective through apertures 412 defined therein. The flange 408 is a portion of an electronic device 404 configured to be received in and supported by a chassis 402.

At 602, a wire gasket is formed from a metallic material so as to define a repeating pattern. For purposes of the present illustration, a wire gasket 410 is formed from metal (i.e., electrically conductive) wire and defines repeating pattern of finger portions (e.g., 204) and raised contact portions 414 and shoulder portions (e.g., 208).

At 604, the wire gasket is joined to the flange by way of the through apertures. For purposes of the present illustration, the wire gasket 410 is mechanically flexed and joined to the flange 408 by receiving respective portions within the through apertures 412. Thus, the wire gasket 410 is joined to the flange 408 in a grasping or “grip-like” engagement, with the raised contact portions 414 extending generally away from the flange 408. The joining of the wire gasket 410 to the flange 408 defines an EMI shielding apparatus (e.g., 300).

At 606, an electronic device is protected against electromagnetic interference EMI by way of the EMI shielding apparatus. For purposes of the present example, the electronic device 404 is fully received within a chassis 402. The raised contact portions 414 are in electrically conductive contact with a metal wall or flange 416 of the chassis 402. The wire gasket 410 functions to prevent EMI from adversely affecting the electronic device 404. Conversely, the wire gasket 410 functions to prevent any EMI generated by the electronic device 404 from having an adverse effect on adjacent or proximate devices or systems.

At 608, the wire gasket is removed from the flange such that the wire gasket and flange are once again separate entities. For purposes of the present example, the wire gasket 410 is removed (or disengaged) from the flange 408 such that the respective entities are separated from each other.

At 610, the wire gasket or the flange (or both) are recycled. For purposes of the present example, wire gasket 410 and the flange 408 are recycled by way of respective processes.

The present teachings contemplate any number of wire gaskets having respective form-factors and being formed from spring-like metal wires. Such a wire gasket is joined to a supported by a flange aspect of another entity by way of received engagement with through apertures. The wire gasket thus makes electrically-conductive contact with the corresponding flange and an entity adjacent to that flange.

The wire gasket is configured to allow airflow or other fluid exchange such that cooling of electronic devices or other entities can be performed. The wire gasket, being electrically conductive, also functions as an EMI shield while bridging the gap between the supportive flange and an adjacent entity in contact with the wire gasket. Wire gaskets according to the present teachings can be positioned to function as EMI shields between adjacent electronic devices, between an electronic device and a portion of a chassis or removable cover, and so on.

Wire gaskets according to the present teachings can be removed from their respective support flanges for reuse, recycling, or other life-cycle considerations. Additionally, a flange for supporting a wire gasket can be planar, curved, and so on, in accordance with the particular form-factor of the wire gasket, the placement of through apertures, and so on.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a flange defining a plurality of through apertures;
a wire gasket defining a repeating pattern of finger portions and contact portions, the wire gasket configured to be removably joined to the flange by way of the through apertures, the wire gasket to electrically couple the flange to an adjacent entity by way of the contact portions, the wire gasket defining an electromagnetic interference (EMI) shield.

2. The apparatus according to claim 1, the flange formed from sheet metal.

3. The apparatus according to claim 1, the wire gasket formed from metal spring wire.

4. The apparatus according to claim 1, the flange defined by a radiused transition from a first portion to a second portion about orthogonal to the first portion.

5. The apparatus according to claim 4, the flange defining a portion of a removable entity, the removable entity configured to be supported at least partially within a chassis.

6. The apparatus according to claim 4, the flange defining a portion of a chassis.

7. The apparatus according to claim 1, the wire gasket configured to removably engage the through apertures along about all of a lengthwise aspect of the flange.

8. The apparatus according to claim 1, the wire gasket configured to make electrically conductive contact with an electronic device supported within a chassis, the flange configured to permit coolant air flow through the apertures.

9. A method, comprising:
forming a wire gasket to define an alternating pattern of finger portions and raised contact portions;
forming a sheet metal to define a flange having a plurality of through apertures; and
removably joining the wire gasket to the flange by way of the through apertures to define an EMI shielding device.

10. The method according to claim 9, the joining the wire gasket to the flange including applying flexing force to the wire gasket while joining the wire gasket to the flange and thereafter ceasing the flexing force such that the wire gasket is removably joined to the flange by way of spring-like engagement.

11. The method according to claim 9, the removably joining the wire gasket to the flange including receiving the finger portions in respective ones of the through apertures.

12. The method according to claim 9, the flange formed from a sheet metal such that a monolithic entity is defined.

13. The method according to claim 9, the flange defining a portion of a chassis, the method including making electrically conductive contact between the wire gasket and an electronic device supported by the chassis.

14. The method according to claim 9 further comprising removing the wire gasket from the flange for recycling.

15. A method, comprising:
forming an EMI shielding device including a wire gasket and a flange, the flange defining apertures there through;
making compliant electrically conductive contact between the EMI shielding device and an electronic device supported by a chassis; and
cooling the electronic device by way of fluid flow through the apertures.
